(19) United States
(12) Patent Application Publication
(10) Pub. No.: US 2025/0036027 A1
(43) Pub. Date: Jan. 30, 2025

(54) COMPOSITION FOR FORMING RESIST UNDERLAYER FILM

(71) Applicant: NISSAN CHEMICAL CORPORATION, Tokyo (JP)

(72) Inventors: Kosuke IGATA, Toyama-shi (JP); Shou SHIMIZU, Toyama-shi (JP); Mamoru TAMURA, Toyama-shi (JP)

(73) Assignee: NISSAN CHEMICAL CORPORATION, Tokyo (JP)

(21) Appl. No.: 18/687,019

(22) PCT Filed: Aug. 17, 2022
(86) PCT No.: PCT/JP2022/031123

§ 371 Date: Sep. 13, 2024

(30) Foreign Application Priority Data
Aug. 27, 2021 (JP) 2021-138741

(51) Int. Cl. G03F 7/039; C08F 220/20; C09D 133/06; G03F 7/038; G03F 7/40; H01L 21/027; H01L 21/308

(52) U.S. Cl. CPC G03F 7/0397; C08F 220/20; C09D 133/068; G03F 7/0382; G03F 7/40; H01L 21/0274; H01L 21/3081

(57) ABSTRACT

A composition for forming a resist underlayer film, the composition including: a polymer containing a unit structure (A) represented by the following formula (1); and a solvent:

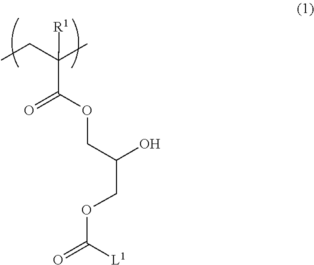

wherein, in the formula (1), R¹ represents a hydrogen atom or an alkyl group having 1 to 10 carbon atoms; and L¹ represents a monovalent organic group selected from an alkyl group having 1 to 10 carbon atoms, an aryl group having 6 to 40 carbon atoms, and a monovalent heterocyclic group, where at least one hydrogen atom which the alkyl group, the aryl group, and the monovalent heterocyclic group have is substituted with a halogen atom, and where at least one hydrogen atom which the alkyl group, the aryl group, and the monovalent heterocyclic group have may be substituted with a hydroxy group.

### TECHNICAL FIELD

The present invention relates to a composition for forming a resist underlayer film that can be used in a lithography process in semiconductor production, particularly in a most advanced (ArF, EUV, EB, etc.) lithography process. The present invention also relates to a method for producing a semiconductor substrate with a resist pattern and a method for producing a semiconductor device to which a resist underlayer film obtained from the composition for forming a resist underlayer film is applied.

### BACKGROUND ART

Conventionally, fine processing by lithography using a resist composition has been performed in manufacturing a semiconductor device. The fine processing is a processing method in which a thin film of a photoresist composition is formed on a semiconductor substrate such as a silicon wafer; irradiation with an active ray such as an ultraviolet ray is performed thereon through a mask pattern drawing a device pattern; development is performed; the obtained photoresist pattern is used as a protective film to etch the substrate; and thereby fine irregularities corresponding to the photoresist pattern is formed on the substrate surface. In recent years, semiconductor devices have been integrated higher and higher. For active lays to be used, in addition to i-line (wavelength: 365 nm), KrF excimer laser (wavelength: 248 nm), and ArF excimer laser (wavelength: 193 nm), which have been conventionally used, EUV light (wavelength: 13.5 nm) or electron beam (EB) have been studied for practical application in order for the most advanced fine processing. Accordingly, it has been a major problem that a defective resist pattern is formed due to an influence from the semiconductor substrate or the like. Therefore, in order to solve this problem, a method of providing a resist underlayer film between the resist and the semiconductor substrate has been widely studied.

Patent Literature 1 discloses a composition for forming an underlayer film for lithography containing a naphthalene ring having a halogen atom. Patent Literature 2 discloses a halogenated antireflection film. Patent Literature 3 discloses a composition for forming a resist underlayer film.

### CITATION LIST

### Patent Literature

Patent Literature 1: WO 2006/003850 A1
Patent Literature 2: JP 2005-526270 A
Patent Literature 3: WO 2020/111068 A1

### SUMMARY OF INVENTION

### Technical Problem

The characteristics required for a resist underlayer film include, for example: not intermixing with a resist film formed as the upper layer (being insoluble in a resist solvent); and having a dry etching rate higher than that of the resist film.

In the case of lithography involving EUV exposure, the line width of the resist pattern to be formed is 32 nm or less, and the resist underlayer film for EUV exposure is formed to be thinner than conventional one. When such a thin film is formed, pinholes, agglomeration, and the like are likely to occur due to the influence of the substrate surface, the polymer to be used, and the like, and it has been difficult to form a uniform film without defects.

On the other hand, when a resist pattern is formed, it is a major problem to improve adhesion of the resist pattern in the development step: in the negative development process in which the unexposed portion of the resist film is removed by using a solvent capable of dissolving the resist film, usually an organic solvent, and the exposed portion of the resist film is left as a resist pattern; and the positive development process in which the exposed portion of the resist film is removed and the unexposed portion of the resist film is left as a resist pattern.

In addition, it is required to suppress deterioration of LWR (Line Width Roughness, or fluctuation (roughness) in line width) at the time of resist pattern formation, to form a resist pattern having a favorable rectangular shape, and to improve resist sensitivity.

In view of the above problems, an object of the present invention is to provide a composition for forming a resist underlayer film to form a resist underlayer film capable of forming a desired resist pattern, a resist underlayer film obtained from the composition for forming a resist underlayer film, and a method for producing a semiconductor substrate having a patterned resist film and a method for producing a semiconductor device using the resist underlayer film.

### Solution to Problem

The present invention includes the following.

[1] A composition for forming a resist underlayer film, the composition including: a polymer containing a unit structure (A) represented by the following formula (1); and a solvent:

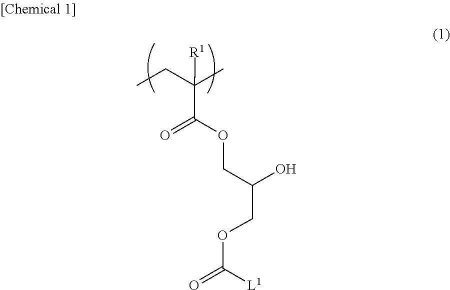

wherein, in the formula (1), R¹ represents a hydrogen atom or an alkyl group having 1 to 10 carbon atoms; and L¹ represents a monovalent organic group selected from an alkyl group having 1 to 10 carbon atoms, an aryl group having 6 to 40 carbon atoms, and a monovalent heterocyclic group, which at least one hydrogen atom which the alkyl group, the aryl group, and the monovalent heterocyclic group have is substituted with a halogen atom, and where at least one hydrogen atom which the alkyl group, the aryl group, and the monovalent heterocyclic group have may be substituted with a hydroxy group.
   [2] The composition for forming a resist underlayer film according to [1], wherein the halogen atom is a fluorine atom or an iodine atom.
   [3] The composition for forming a resist underlayer film according to [1] or [2], wherein the polymer further contains a unit structure (B) that has a side chain having a monovalent organic group selected from an alkyl group having 1 to 10 carbon atoms, an aliphatic ring having 3 to 10 carbon atoms, and an aryl group having 6 to 40 carbon atoms.
   [4] The composition for forming a resist underlayer film according to [3], wherein the unit structure (B) is represented by the following formula (2):

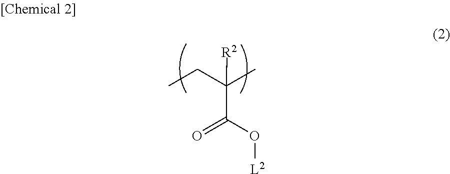

wherein, in the formula (2), R² represents a hydrogen atom or an alkyl group having 1 to 10 carbon atoms; and L² represents a monovalent organic group selected from an alkyl group having 1 to 10 carbon atoms and an aryl group having 6 to 40 carbon atoms, where at least one hydrogen atom which the alkyl group and the aryl group have may be substituted with a hydroxy group.
   [5] The composition for forming a resist underlayer film according to any one of [1] to [4], the composition further including an acid generator.
   [6] The composition for forming a resist underlayer film according to any one of [1] to [5], the composition further including a crosslinking agent.
   [7] A resist underlayer film, being a baked product of a coating film formed from the composition for forming a resist underlayer film according to any one of [1] to [6].
   [8] A method for producing a semiconductor substrate having a patterned resist film, the method including:
a step of applying the composition for forming a resist underlayer film according to any one of [1] to [6] on a semiconductor substrate, followed by baking, to form a resist underlayer film;
a step of applying a resist on the resist underlayer film, followed by baking, to form a resist film;
a step of exposing the semiconductor substrate coated with the resist underlayer film and the resist film; and
a step of developing the exposed resist film to subject the resist film to patterning.
   [9] A method for producing a semiconductor device, the method including:
a step of forming a resist underlayer film formed from the composition for forming a resist underlayer film according to any one of [1] to [6] on a semiconductor substrate;
a step of forming a resist film on the resist underlayer film;
a step of irradiating the resist film with light or an electron beam, followed by development, to form a resist pattern;
a step of etching the resist underlayer film through the formed resist pattern to form a patterned resist underlayer film; and
a step of processing the semiconductor substrate through the patterned resist underlayer film.

### Advantageous Effects of Invention

The composition for forming a resist underlayer film of the present invention has excellent coating properties on a semiconductor substrate to be processed, and has excellent adhesion at the interface between the resist and the resist underlayer film during resist pattern formation, so that a good resist pattern can be formed without causing peeling of the resist pattern. In addition, a good resist pattern can be formed even with a low exposure amount. That is, the upper resist layer has higher sensitivity. In particular, a remarkable effect is exhibited during EUV light (wavelength: 13.5 nm) exposure or EB (electron beam) exposure.

### DESCRIPTION OF EMBODIMENTS

### <Composition for Forming a Resist Underlayer Film>

The composition for forming a resist underlayer film of the present invention includes: a polymer containing a unit structure (A) represented by the following formula (1); and a solvent.

### (Unit Structure (A))

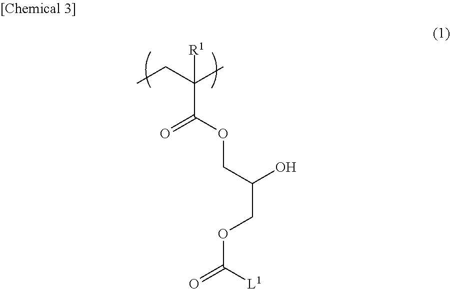

wherein, in the formula (1), R¹ represents a hydrogen atom or an alkyl group having 1 to 10 carbon atoms; and L¹ represents a monovalent organic group selected from an alkyl group having 1 to 10 carbon atoms, an aryl group having 6 to 40 carbon atoms, and a monovalent heterocyclic group, where at least one hydrogen atom which the alkyl group, the aryl group, and the monovalent heterocyclic group have is substituted with a halogen atom, and where at least one hydrogen atom which the alkyl group, the aryl group, and the monovalent heterocyclic group have may be substituted with a hydroxy group.

Examples of the alkyl group having 1 to 10 carbon atoms include a methyl group, an ethyl group, a n-propyl group, an i-propyl group, a cyclopropyl group, a n-butyl group, an i-butyl group, a s-butyl group, a t-butyl group, a cyclobutyl group, a 1-methyl-cyclopropyl group, a 2-methyl-cyclopropyl group, a n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, a n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, a 1-ethyl-2-methyl-n-propyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, a 2-ethyl-3-methyl-cyclopropyl group, a n-heptyl group, a cycloheptyl group, a norbornyl group, a n-octyl group, a cyclooctyl group, a n-nonyl group, an isobornyl group, a tricyclononyl group, a n-decyl group, an adamantyl group, and a tricyclodecyl group.

Examples of the aryl group having 6 to 40 carbon atoms include a phenyl group, an o-methylphenyl group, an m-methylphenyl group, a p-methylphenyl group, an o-chlorophenyl group, an m-chlorophenyl group, a p-chlorophenyl group, an o-fluorophenyl group, a p-fluorophenyl group, an o-methoxyphenyl group, a p-methoxyphenyl group, a p-nitrophenyl group, a p-cyanophenyl group, an α-naphthyl group, a β-naphthyl group, an o-biphenylyl group, an m-biphenylyl group, a p-biphenylyl group, a 1-anthryl group, a 2-anthryl group, a 9-anthryl group, a 1-phenanthryl group, a 2-phenanthryl group, a 3-phenanthryl group, a 4-phenanthryl group, and a 9-phenanthryl group.

Examples of the heterocycle in the monovalent heterocyclic group include furan, thiophene, pyrrole, imidazole, pyran, pyridine, pyrimidine, pyrazine, pyrrolidine, piperidine, piperazine, morpholine, indole, purine, quinoline, isoquinoline, quinuclidine, chromene, thianthrene, phenothiazine, phenoxazine, xanthene, acridine, phenazine, carbazole, triazinone, triazinedione, and triazinetrione.

Examples of the halogen atom include a fluorine atom, a chlorine atom, a bromine atom, and an iodine atom, and the halogen atom is preferably a fluorine atom or an iodine atom.

The polymer containing the repeating unit represented by the formula (1) can be obtained, for example, by reacting a compound having a carboxy group with a glycidyl methacrylate polymer as described below.

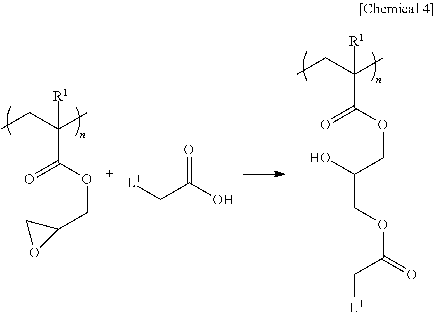

(In the above formula, R¹ and L¹ are the same as described above.)

Examples of the repeating unit of the polymer produced by the above reaction formula are as follows.

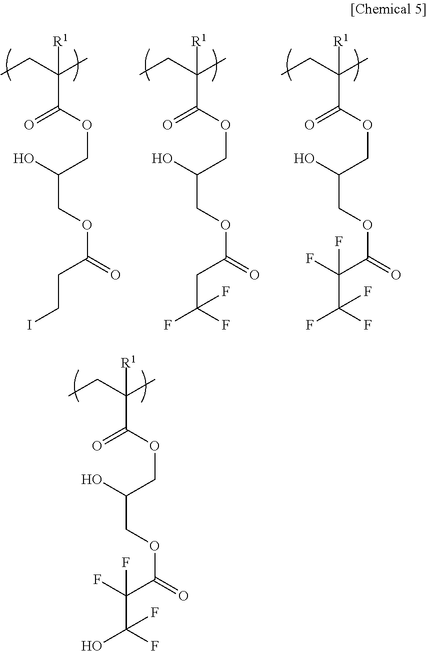

Specific structures of L¹ are as follows.

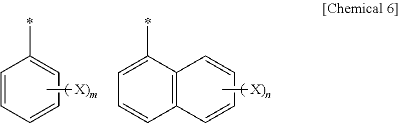

(In the above formulae, X represents a halogen atom, and m represents an integer of 1 to 5. “n” represents an integer of 1 to 7. * represents a bonding arm.)

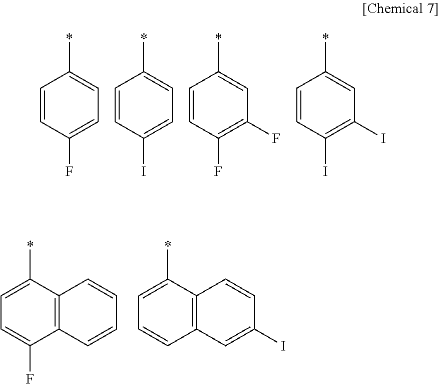

(* represents a bonding arm.)

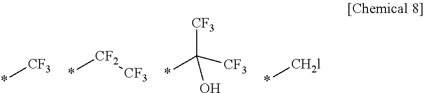

(* represents a bonding arm.)

### (Unit Structure (B))

The polymer may further contain a unit structure (B) that has a side chain having a monovalent organic group selected from an alkyl group having 1 to 10 carbon atoms, an aliphatic ring having 3 to 10 carbon atoms, and an aryl group having 6 to 40 carbon atoms.

The unit structure (B) may be represented by the following formula (2).

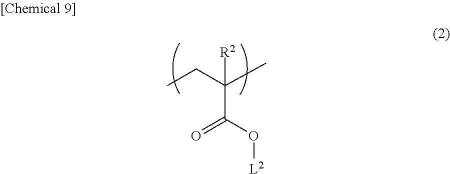

wherein, in the formula (2), R² represents a hydrogen atom or an alkyl group having 1 to 10 carbon atoms; and L² represents a monovalent organic group selected from an alkyl group having 1 to 10 carbon atoms and an aryl group having 6 to 40 carbon atoms, where at least one hydrogen atom which the alkyl group and the aryl group have may be substituted with a hydroxy group.

Examples of the alkyl group having 1 to 10 carbon atoms represented by R² and the alkyl group having 1 to 10 carbon atoms represented by L² are as described above.

Specific examples of the monomer structure used for deriving the formula (2) include the following compounds.

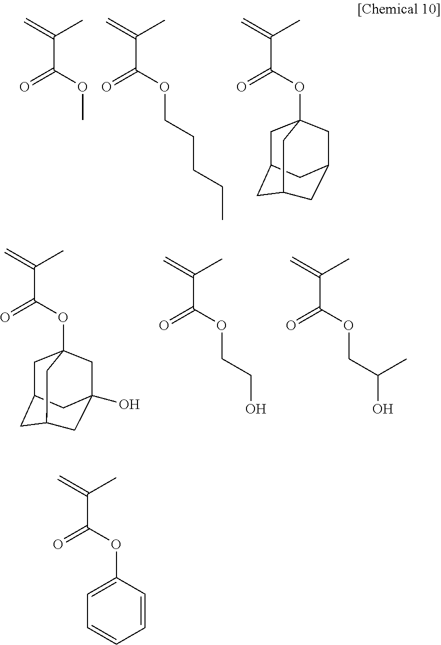

The polymer can be produced, for example, by polymerizing a monomer by a known method shown in Examples.

The molar ratio of the formula (1) may be, for example, 20 to 100 mol %, or may be 20 mol % or more and less than 100 mol %, with respect to the whole of the polymer.

The molar ratio of the formula (2) may be, for example, 0 to 80 mol %, or may be more than 0 mol % and 80 mol % or less, with respect to the whole of the polymer.

The polymer may contain a third component other than the formula (1) and the formula (2) as long as the effect of the composition of the present application is exhibited. In this case, the molar ratio of the third component is, for example, 0 to 20 mol % with respect to the whole of the polymer.

The lower limit of the weight average molecular weight of the polymer is, for example, 500, 1,000, 2,000, or 3,000, and the upper limit of the weight average molecular weight of the polymer is, for example, 30,000, 20,000, or 10,000.

### <Solvent>

The solvent to be used in the composition for forming a resist underlayer film of the present application is not particularly limited as long as it is a solvent capable of uniformly dissolving a contained component that is solid at normal temperature such as the polymer, but an organic solvent generally used in a chemical solution for a semiconductor lithography process is preferable. Specific examples thereof include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl-2-hydroxyisobutyrate, ethyl-2-hydroxyisobutyrate, ethyl ethoxyacetate, 2-hydroxyethyl acetate, methyl-3-methoxypropionate, ethyl-3-methoxypropionate, ethyl-3-ethoxypropionate, methyl-3-ethoxypropionate, methyl pyruvate, ethyl pyruvate, ethyl acetate, butyl acetate, ethyl lactate, butyl lactate, 2-heptanone, methoxy cyclopentane, anisole, γ-butyrolactone, N-methylpyrrolidone, N,N-dimethylformamide, and N,N-dimethylacetamide. These solvents can be used alone or in combination of two or more kinds thereof.

Among these solvents, propylene glycol monomethyl ether, propylene glycol monomethyl ether acetate, ethyl lactate, butyl lactate, and cyclohexanone are preferable. In particular, propylene glycol monomethyl ether and propylene glycol monomethyl ether acetate are preferable.

### <Acid Generator>

As the acid generator contained as an optional component in the composition for forming a resist underlayer film of the present invention, both a thermal acid generator and a photoacid generator can be used, but it is preferable to use a thermal acid generator.

Examples of the thermal acid generator include sulfonic acid compounds and carboxylic acid compounds such as p-toluenesulfonic acid, trifluoromethanesulfonic acid, pyridinium-p-toluenesulfonate (pyridinium-p-toluenesulfonic acid), pyridinium phenol sulfonic acid, pyridinium-p-hydroxybenzenesulfonic acid (pyridinium salt of p-phenolsulfonic acid), pyridinium-trifluoromethanesulfonic acid, salicylic acid, camphorsulfonic acid, 5-sulfosalicylic acid, 4-chlorobenzenesulfonic acid, 4-hydroxybenzenesulfonic acid, benzenedisulfonic acid, 1-naphthalenesulfonic acid, citric acid, benzoic acid, and hydroxybenzoic acid.

Examples of the photoacid generator include an onium salt compound, a sulfonimide compound, and a disulfonyldiazomethane compound.

Specific examples of the onium salt compound include iodonium salt compounds such as diphenyliodonium hexafluorophosphate, diphenyliodonium trifluoromethanesulfonate, diphenyliodonium nonafluoronormal butanesulfonate, diphenyliodonium perfluoronormal octanesulfonate, diphenyliodonium camphor sulfonate, bis(4-tert-butylphenyl)iodonium camphor sulfonate, and bis(4-tert-butylphenyl)iodonium trifluoromethanesulfonate; and sulfonium salt compounds such as triphenylsulfonium hexafluoroantimonate, triphenylsulfonium nonafluoronormal butanesulfonate, triphenylsulfonium camphor sulfonate, and triphenylsulfonium trifluoromethanesulfonate.

Specific examples of the sulfonimide compound include N-(trifluoromethanesulfonyloxy)succinimide, N-(nonafluoronormalbutanesulfonyloxy)succinimide, N-(camphorsulfonyloxy)succinimide, and N-(trifluoromethanesulfonyloxy)naphthalimide.

Specific examples of the disulfonyl diazomethane compound include bis(trifluoromethylsulfonyl) diazomethane, bis(cyclohexylsulfonyl) diazomethane, bis(phenylsulfonyl) diazomethane, bis(p-toluenesulfonyl) diazomethane, bis(2,4-dimethylbenzenesulfonyl) diazomethane, methylsulfonyl-p-toluenesulfonyl diazomethane, and the like.

Only one kind of the acid generator can be used, or two or more kinds thereof can be used in combination.

When the acid generator is used, the content ratio of the acid generator is, for example, 0.1 to 50 mass %, preferably 1 to 30 mass % with respect to the following crosslinking agent.

### <Crosslinking Agent>

The crosslinking agent contained as an optional component in the composition for forming a resist underlayer film of the present invention has a functional group that reacts with a secondary hydroxyl group of the polymer.

Examples of the crosslinking agent include hexamethoxymethylmelamine, tetramethoxymethylbenzoguanamine, 1,3,4,6-tetrakis(methoxymethyl) glycoluril (tetramethoxymethyl glycoluril) (POWDERLINK® 1174), 1,3,4,6-tetrakis(butoxymethyl) glycoluril, 1,3,4,6-tetrakis(hydroxymethyl) glycoluril, 1,3-bis(hydroxymethyl) urea, 1,1,3,3-tetrakis(butoxymethyl) urea, and 1,1,3,3-tetrakis(methoxymethyl) urea.

In addition, the crosslinking agent of the present invention may be a nitrogen-containing compound having 2 to 6 substituents represented by the following formula (1d) and bonded to a nitrogen atom in one molecule, which is described in WO 2017/187969 A1.

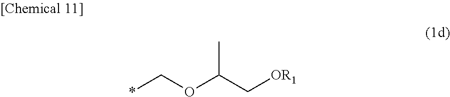

(In the formula (1d), R₁ represents a methyl group or an ethyl group. * represents a bonding arm to be bonded to a nitrogen atom.)

The nitrogen-containing compound having 2 to 6 substituents represented by the formula (1d) in one molecule may be a glycoluril derivative represented by the following formula (1E).

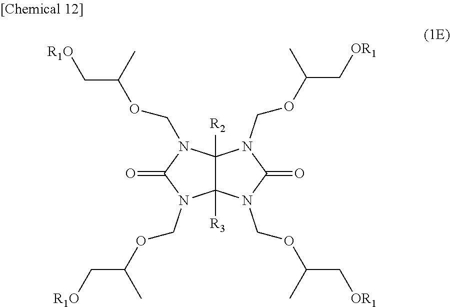

(In the formula (1E), four R₁s each independently represent a methyl group or an ethyl group, and R₂ and R₃ each independently represent a hydrogen atom, an alkyl group having 1 to 4 carbon atoms, or a phenyl group.)

Examples of the glycoluril derivative represented by the formula (1E) include compounds represented by the following formulae (1E-1) to (1E-6).

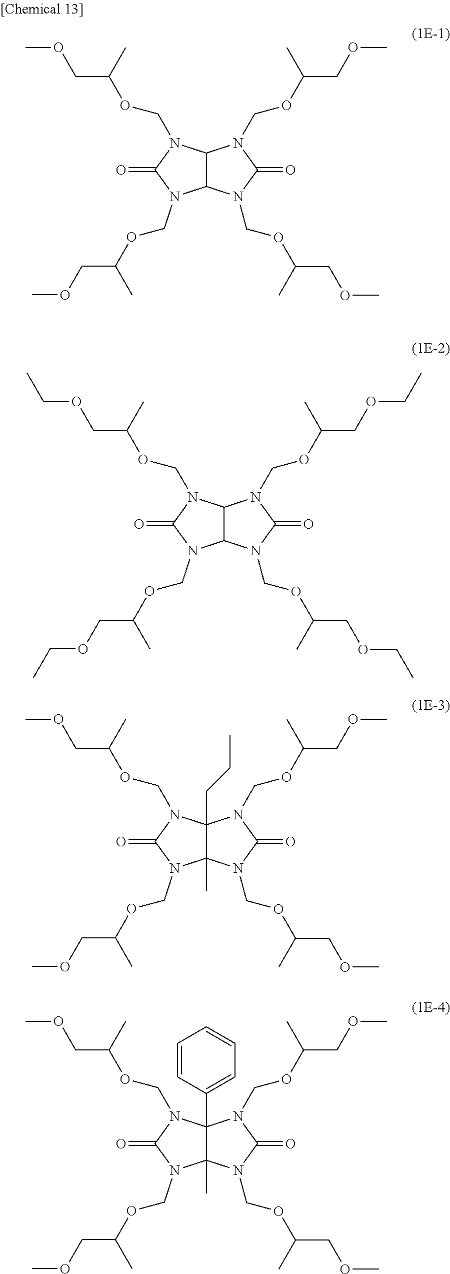

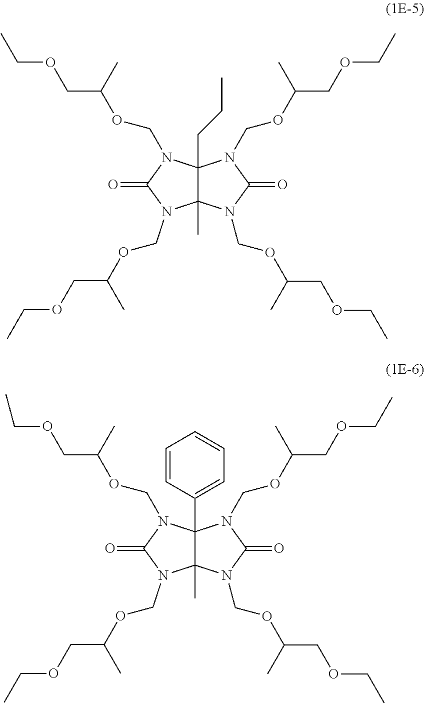

The nitrogen-containing compound having 2 to 6 substituents represented by the formula (1d) in one molecule is obtained by reacting a nitrogen-containing compound having 2 to 6 substituents represented by the following formula (2d) and bond to a nitrogen atom in one molecule with at least one compound represented by the following formula (3d).

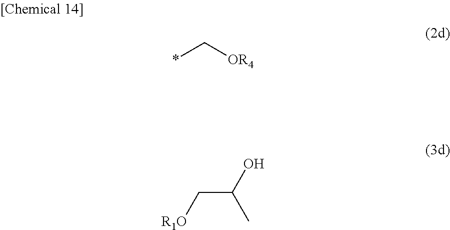

(In the formula (2d) and the formula (3d), R₁ represents a methyl group or an ethyl group, and R₄ represents an alkyl group having 1 to 4 carbon atoms. * represents a bonding arm to be bonded to a nitrogen atom.)

The glycoluril derivative represented by the formula (1E) is obtained by reacting a glycoluril derivative represented by the following formula (2E) with at least one compound represented by the formula (3d).

The nitrogen-containing compound having 2 to 6 substituents represented by the formula (2d) in one molecule is, for example, a glycoluril derivative represented by the following formula (2E).

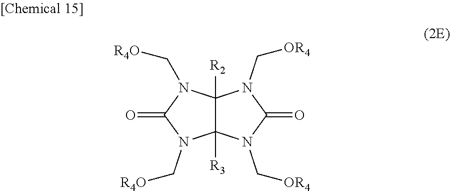

(In the formula (2E), R₂ and R₃ each independently represent a hydrogen atom, an alkyl group having 1 to 4 carbon atoms, or a phenyl group, and R₄ each independently represents an alkyl group having 1 to 4 carbon atoms.)

Examples of the glycoluril derivative represented by the formula (2E) include compounds represented by the following formulae (2E-1) to (2E-4). Furthermore, examples of the compound represented by the formula (3d) include compounds represented by the following formulae (3d-1) and (3d-2).

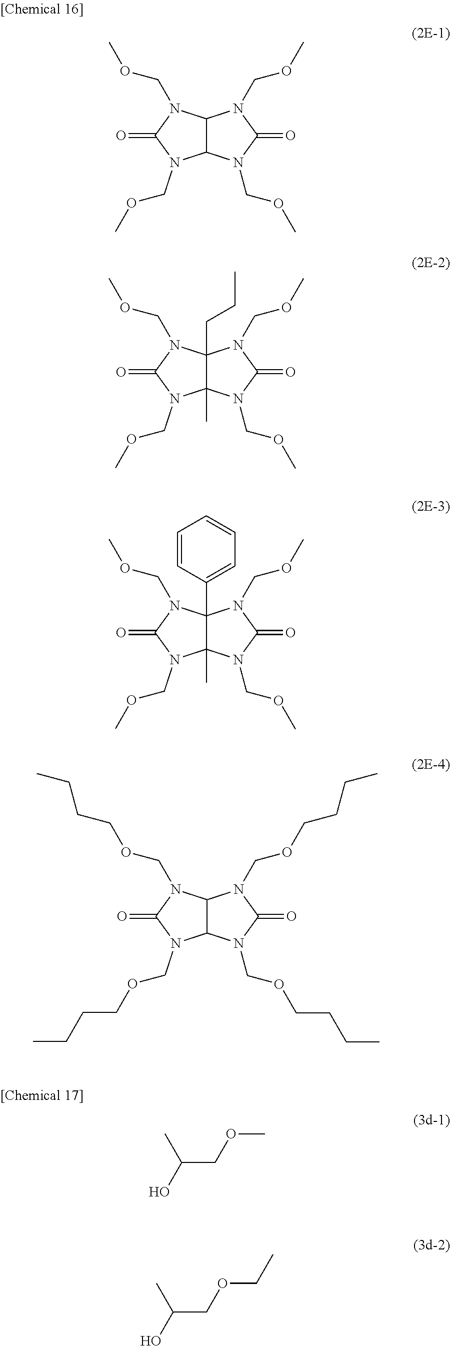

For the detail of the nitrogen-containing compound having 2 to 6 substituents represented by the formula (1d) and bond to a nitrogen atom in one molecule, the entire disclosure of WO 2017/187969 A1 is incorporated in the present application.

When the crosslinking agent is used, the content ratio of the crosslinking agent is, for example, 1 to 50 mass %, preferably 5 to 30 mass % with respect to the polymer.

### <Other Components>

In the composition for forming a resist underlayer film of the present invention, a surfactant can be further added in order to avoid occurrence of pinholes, striations, or the like, and further improve the coating property for surface unevenness. Examples of the surfactant include nonionic surfactants, such as: polyoxyethylene alkyl ethers, such as polyoxyethylene lauryl ether, polyoxyethylene stearyl ether, polyoxyethylene cetyl ether, and polyoxyethylene oleyl ether, polyoxyethylene alkyl allyl ethers, such as polyoxyethylene octyl phenol ether and polyoxyethylene nonyl phenol ether, polyoxyethylene/polyoxypropylene block copolymers, sorbitan fatty acid esters, such as sorbitan monolaurate, sorbitan monopalmitate, sorbitan monostearate, sorbitan monooleate, sorbitan trioleate, and sorbitan tristearate, and polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-based surfactants, such as EFUTOP EF301, EF303, and EF352 (trade name, manufactured by TOKEM PRODUCTS), MEGAFACE F171, F173, and R-30 (trade name, manufactured by DIC Corporation), Fluorad FC430, FC431 (trade name, manufactured by Sumitomo 3M Limited), and AsahiGuard AG710, Surflon S-382, SC101, SC102, SC103, SC104, SC105, and SC106 (trade name, manufactured by Asahi Glass Co., Ltd.); and KP 341, an organosiloxane polymer (manufactured by Shin-Etsu Chemical Co., Ltd.). The blending amount of these surfactants is usually 2.0 mass % or less, and preferably 1.0 mass % or less with respect to the total solid content of the composition for forming a resist underlayer film of the present invention. These surfactants may be added alone, or may be added in combination of two or more thereof.

The solid content contained in the composition for forming a resist underlayer film of the present invention, that is, the components excluding the solvent is, for example, 0.01 to 10 mass %.

### <Resist Underlayer Film>

The resist underlayer film according to the present invention can be produced, for example, by applying the above-described composition for forming a resist underlayer film onto a semiconductor substrate and baking the composition.

The resist underlayer film is a baked product of a coating film formed from the composition for forming a resist underlayer film.

Examples of the semiconductor substrate to which the composition for forming a resist underlayer film of the present invention is applied include silicon wafers, germanium wafers, and compound semiconductor wafers such as gallium arsenide, indium phosphide, gallium nitride, indium nitride, and aluminum nitride.

When a semiconductor substrate having an inorganic film formed on the surface thereof is used, the inorganic film is formed by, for example, an atomic layer deposition (ALD) method, a chemical vapor deposition (CVD) method, a reactive sputtering method, an ion plating method, a vacuum deposition method, or a spin coating method (spin on glass: SOG). Examples of the inorganic film include a polysilicon film, a silicon oxide film, a silicon nitride film, a boro-phospho silicate glass (BPSG) film, a titanium nitride film, a titanium nitride oxide film, a tungsten film, a gallium nitride film, and a gallium arsenide film.

The composition for forming a resist underlayer film of the present invention is applied onto such a semiconductor substrate by an appropriate application method such as a spinner or a coater. Thereafter, baking is performed using a heating unit such as a hot plate to form a resist underlayer film. The baking conditions are appropriately selected from a baking temperature of 100 to 400° C. and a baking time of 0.3 to 60 minutes. Preferably, the baking temperature is 120 to 350° C., and the baking time is 0.5 to 30 minutes. More preferably, the baking temperature is 150 to 300° C., and the baking time is 0.8 to 10 minutes.

The thickness of the resist underlayer film to be formed is, for example, 0.001 μm (1 nm) to 10 μm, 0.002 μm (2 nm) to 1 μm, 0.005 μm (5 nm) to 0.5 μm (500 nm), 0.001 μm (1 nm) to 0.05 μm (50 nm), 0.002 μm (2 nm) to 0.05 μm (50 nm), 0.003 μm (3 nm) to 0.05 μm (50 nm), 0.004 μm (4 nm) to 0.05 μm (50 nm), 0.005 μm (5 nm) to 0.05 μm (50 nm), 0.003 μm (3 nm) to 0.03 μm (30 nm), 0.003 μm (3 nm) to 0.02 μm (20 nm), and 0.005 μm (5 nm) to 0.02 μm (20 nm). When the temperature during baking is lower than the above range, crosslinking becomes insufficient. On the other hand, when the temperature during baking is higher than the above range, the resist underlayer film may be decomposed by heat.

### <Method for Producing Semiconductor Substrate Having Patterned Resist Film and Method for Producing Semiconductor Device>

The method for producing a semiconductor substrate having a patterned resist film includes at least the following steps.
Step of applying the composition for forming a resist underlayer film of the present invention on a semiconductor substrate, followed by baking, to form a resist underlayer film
Step of applying a resist on the resist underlayer film, followed by baking, to form a resist film
Step of exposing the semiconductor substrate coated with the resist underlayer film and the resist film
Step of developing the exposed resist film to subject the resist film to patterning

The method for producing a semiconductor device includes at least the following steps.
Step of forming a resist underlayer film formed from the composition for forming a resist underlayer film of the present invention on a semiconductor substrate
Step of forming a resist film on the resist underlayer film
Step of irradiating the resist film with light or an electron beam, followed by development, to form a resist pattern
Step of etching the resist underlayer film through the formed resist pattern to form a patterned resist underlayer film
Step of processing the semiconductor substrate through the patterned resist underlayer film

The method for producing a semiconductor substrate having a patterned resist film and the method for producing a semiconductor device includes, for example, the following steps. In the production, a photoresist layer is usually formed on the resist underlayer film. The photoresist formed by coating and baking on the resist underlayer film by a known method is not particularly limited as long as it is sensitive to light used for exposure. Both a negative photoresist and a positive photoresist can be used. Examples thereof include: a positive photoresist containing a novolak resin and 1,2-naphthoquinone diazide sulfonic acid ester; a chemically amplified photoresist containing a binder having a group that is decomposed by an acid to increase the alkali dissolution rate and a photoacid generator; a chemically amplified photoresist containing a low molecular compound that is decomposed by an acid to increase the alkali dissolution rate of the photoresist, an alkali-soluble binder, and a photoacid generator; a chemically amplified photoresist containing a binder having a group that is decomposed by an acid to increase the alkali dissolution rate, a low molecular compound that is decomposed by an acid to increase the alkali dissolution rate of the photoresist, and a photoacid generator; and a resist containing a metal element. Specific examples thereof include V146G (trade name) manufactured by JSR Corporation, APEX-E (trade name) manufactured by SIPLAY, PAR710 (trade name) manufactured by SUMITOMO CHEMICAL COMPANY, and AR2772 and SEPR430 (trade name) manufactured by Shin-Etsu Chemical Co., Ltd. Further, examples thereof include a fluorine atom-containing polymer-based photoresist as described in Proc. SPIE, Vol. 3999, 330-334 (2000), Proc. SPIE, Vol. 3999, 357-364 (2000), or Proc. SPIE, Vol. 3999, 365-374 (2000).

It is possible to use, but are not limited to, so-called resist compositions and metal-containing resist compositions such as resist compositions, radiation-sensitive resin compositions, and high-resolution patterning compositions based on an organometallic solution disclosed in WO2019/188595, WO2019/187881, WO2019/187803, WO2019/167737, WO2019/167725, WO2019/187445, WO2019/167419, WO2019/123842, WO2019/054282, WO2019/058945, WO2019/058890, WO2019/039290, WO2019/044259, WO2019/044231, WO2019/026549, WO2018/193954, WO2019/172054, WO2019/021975, WO2018/230334, WO2018/194123, JP2018-180525, WO2018/190088, JP2018-070596, JP2018-028090, JP2016-153409, JP2016-130240, JP2016-108325, JP2016-047920, JP2016-035570, JP2016-035567, JP2016-035565, JP2019-101417, JP2019-117373, JP2019-052294, JP2019-008280, JP2019-008279, JP2019-003176, JP2019-003175, JP2018-197853, JP2019-191298, JP2019-061217, JP2018-045152, JP2018-022039, JP2016-090441, JP2015-10878, JP2012-168279, JP2012-022261, JP2012-022258, JP2011-043749, JP2010-181857, JP2010-128369, WO2018/031896, JP2019-113855, WO2017/156388, WO2017/066319, JP2018-41099, WO2016/065120, WO2015/026482, JP2016-29498, JP2011-253185, and the like.

Examples of the resist composition include the following compositions.

An active ray-sensitive or radiation-sensitive resin composition including: a resin A having a repeating unit having an acid-decomposable group in which a polar group is protected by a protecting group that is eliminated by the action of an acid; and a compound represented by the following general formula (21).

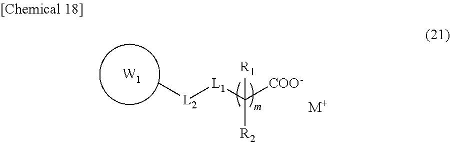

In the general formula (21), “m” represents an integer of 1 to 6.
R₁ and R² each independently represent a fluorine atom or a perfluoroalkyl group.
L₁ represents —O—, —S—, —COO—, —SO₂—, or —SO₃—.
L₂ represents an alkylene group optionally having a substituent or a single bond.
W₁ represents a cyclic organic group optionally having a substituent.
M⁺ represents a cation.

A metal-containing film-forming composition for extreme ultraviolet ray or electron beam lithography, including: a compound having a metal-oxygen covalent bond; and a solvent, wherein metal elements constituting the compound belong to the periods 3 to 7 of the groups 3 to 15 of the periodic table.

A radiation-sensitive resin composition including: a polymer having a first structural unit represented by the following formula (31) and a second structural unit represented by the following formula (32) and containing an acid-dissociable group; and an acid generator.

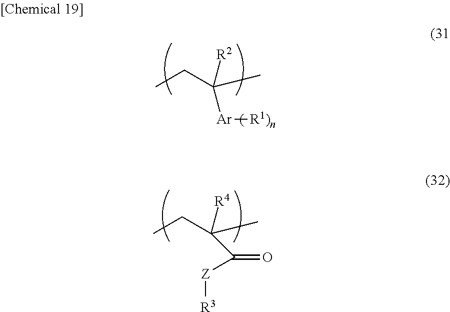

(In the formula (31), Ar is a group obtained by removing (n+1) hydrogen atoms from an arene having 6 to 20 carbon atoms. R¹ is a hydroxy group, a sulfanyl group, or a monovalent organic group having 1 to 20 carbon atoms. “n” represents an integer of 0 to 11. When “n” is 2 or more, a plurality of R s is the same or different. R² is a hydrogen atom, a fluorine atom, a methyl group, or a trifluoromethyl group. In the formula (32), R³ is a monovalent group having 1 to 20 carbon atoms and containing the acid-dissociable group. Z is a single bond, an oxygen atom, or a sulfur atom. R⁴ is a hydrogen atom, a fluorine atom, a methyl group, or a trifluoromethyl group.)

A resist composition including: a resin (A1) containing a structural unit having a cyclic carbonate ester structure, a structural unit represented by the following formula, and a structural unit having an acid-unstable group; and an acid generator.

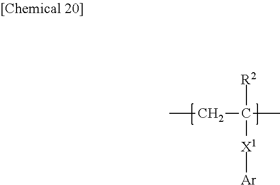

In the formula,
R² represents an alkyl group having 1 to 6 carbon atoms that may have a halogen atom, a hydrogen atom, or a halogen atom; and X¹ represents a single bond, —CO—O—*, or —CO—NR⁴—*, * represents a bonding arm with —Ar, R⁴ represents a hydrogen atom or an alkyl group having 1 to 4 carbon atoms, and Ar represents an aromatic hydrocarbon group having 6 to 20 carbon atoms that may have one or more groups selected from the group consisting of a hydroxy group and a carboxyl group.

Examples of the resist film include the following.

A resist film containing a base resin containing: a repeating unit represented by the following formula (a1) and/or a repeating unit represented by the following formula (a2); and a repeating unit that generates an acid bonded to a polymer main chain by exposure.

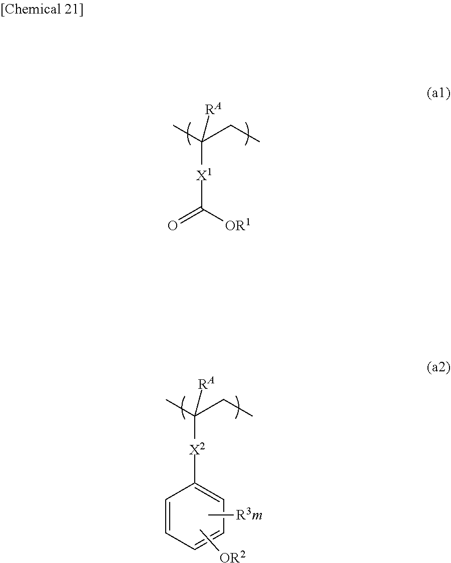

(In the formula (a1) and the formula (a2), R^{A} is each independently a hydrogen atom or a methyl group. R¹ and R² are each independently a tertiary alkyl group having 4 to 6 carbon atoms. R³s each independently represent a fluorine atom or a methyl group. “m” is an integer of 0 to 4. X¹ is a single bond, a phenylene group, a naphthylene group, or a linking group having 1 to 12 carbon atoms and containing at least one selected from an ester bond, a lactone ring, a phenylene group, and a naphthylene group. X² is a single bond, an ester bond, or an amide bond.)

Examples of the resist material include the following.

A resist material containing a polymer having a repeating unit represented by the following formula (b1) or formula (b2).

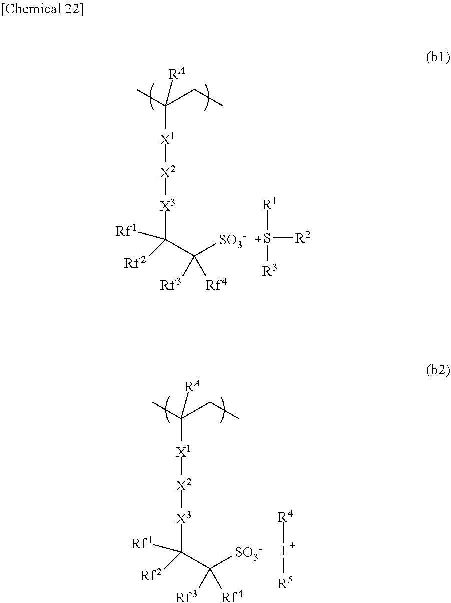

(In the formula (b1) and the formula (b2), R^{A} is a hydrogen atom or a methyl group. X¹ is a single bond or an ester group. X² is a linear, branched or cyclic alkylene group having 1 to 12 carbon atoms or an arylene group having 6 to 10 carbon atoms, and a part of the methylene groups constituting the alkylene group may be substituted with an ether group, an ester group, or a lactone ring-containing group, and at least one hydrogen atom contained in X² is substituted with a bromine atom. X³ is a single bond, an ether group, an ester group, or a linear, branched or cyclic alkylene group having 1 to 12 carbon atoms, and a part of the methylene groups constituting the alkylene group may be substituted with an ether group or an ester group. Rf¹ to Rf⁴ are each independently a hydrogen atom, a fluorine atom, or a trifluoromethyl group, and at least one of Rf¹ to Rf⁴ is a fluorine atom or a trifluoromethyl group. In addition, Rf¹ and Rf² may be combined to form a carbonyl group. R¹ to R⁵ are each independently a linear, branched, or cyclic alkyl group having 1 to 12 carbon atoms, a linear, branched, or cyclic alkenyl group having 2 to 12 carbon atoms, an alkynyl group having 2 to 12 carbon atoms, an aryl group having 6 to 20 carbon atoms, an aralkyl group having 7 to 12 carbon atoms, or an aryloxyalkyl group having 7 to 12 carbon atoms, and some or all of the hydrogen atoms of these groups may be substituted with a hydroxy group, a carboxy group, a halogen atom, an oxo group, a cyano group, an amide group, a nitro group, a sultone group, a sulfone group, or a sulfonium salt-containing group, and some of the methylene groups constituting these groups may be substituted with an ether group, an ester group, a carbonyl group, a carbonate group, or a sulfonic acid ester group. R¹ and R² may be bonded to form a ring together with the sulfur atom to which they are bonded.)

A resist material containing a base resin containing a polymer containing a repeating unit represented by the following formula (a).

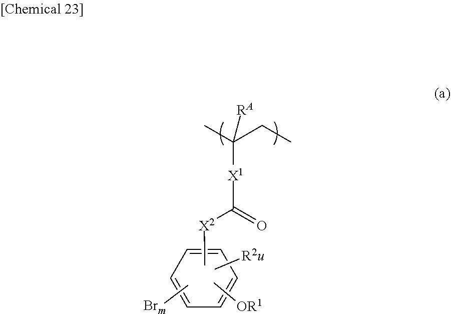

(In the formula (a), R^{A} is a hydrogen atom or a methyl group. R is a hydrogen atom or an acid-unstable group. R² is a linear, branched, or cyclic alkyl group having 1 to 6 carbon atoms, or a halogen atom other than bromine. X¹ is a single bond, a phenylene group, or a linear, branched, or cyclic alkylene group having 1 to 12 carbon atoms that may contain an ester group or a lactone ring. X² is —O—, —O—CH₂—, or —NH—. “m” is an integer of 1 to 4. “u” is an integer of 0 to 3. Here, m+u is an integer of 1 to 4.)

A resist composition that generates an acid by exposure and changes in solubility in a developer by an action of an acid, including:
a base material component (A) that changes in solubility in a developer by an action of an acid, and a fluorine additive component (F) that exhibits decomposability in an alkaline developer,
wherein the fluorine additive component (F) contains a fluororesin component (F1) having a structural unit (f1) containing a base dissociable group and a constituent unit (f2) containing a group represented by the following general formula (f2-r-1).

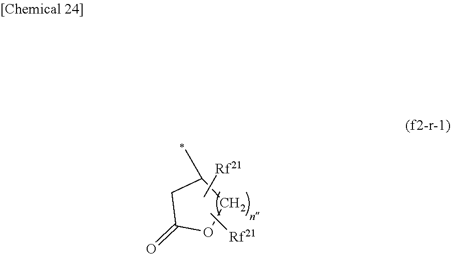

[In the formula (f2-r-1), Rf²¹ each independently represents a hydrogen atom, an alkyl group, an alkoxy group, a hydroxyl group, a hydroxyalkyl group, or a cyano group. n″ is an integer of 0 to 2. * is a bonding arm.]

The structural unit (f1) includes a constituent unit represented by the following general formula (f1-1) or a constituent unit represented by the following general formula (f1-2).

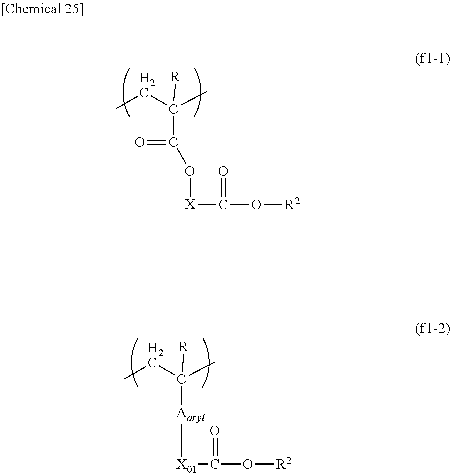

[In the formulae (f1-1) and (f1-2), Rs each independently represent a hydrogen atom, an alkyl group having 1 to 5 carbon atoms, or a halogenated alkyl group having 1 to 5 carbon atoms. X is a divalent linking group having no acid-dissociable site. A_{aryl} is a divalent aromatic cyclic group that may have a substituent. X₀₁ is a single bond or a divalent linking group. R² is each independently an organic group having a fluorine atom.]

Examples of the coating, the coating solution, and the coating composition include the following.

A coating including a metal oxo-hydroxo network having an organic ligand via a metal carbon bond and/or a metal carboxylate bond.

An inorganic oxo/hydroxo-based composition.

A coating solution including: an organic solvent; a first organometallic composition represented by the formula R_{z}SnO_{(2-(z/2)-(x/2))}(OH)ₓ (where 0<z≤2 and 0<(z+x)≤4), the formula R′ₙSnX₄₋ₙ (where n=1 or 2), or a mixture thereof, wherein R and R′ are independently a hydrocarbyl group having 1 to 31 carbon atoms, and X is a ligand having a hydrolysable bond to Sn or a combination thereof; and a hydrolyzable metal compound represented by the formula MX′ᵥ (wherein M is a metal selected from the group 2 to 16 of the element periodic table, “v” is a number satisfying v=2 to 6, and X′ is a ligand having a hydrolysable M-X bond or a combination thereof).

A coating solution including an organic solvent and a first organometallic compound represented by the formula RSnO_{(3/2-x/2)}(OH)ₓ (wherein 0<x<3), wherein the solution includes tin in an amount of about 0.0025 to 1.5 M, R is an alkyl group or a cycloalkyl group having 3 to 31 carbon atoms, and the alkyl group or the cycloalkyl group is bonded to tin at a secondary or tertiary carbon atom.

An inorganic patterning precursor aqueous solution including a mixture of water, a metal suboxide cation, a polyatomic inorganic anion, and a radiation-sensitive ligand including a peroxide group.

The exposure is performed through a mask (reticle) for forming a predetermined pattern, and for example, i-ray, KrF excimer laser, ArF excimer laser, EUV (extreme ultraviolet ray), or EB (electron beam) is used, and the composition for forming a resist underlayer film of the present invention is preferably applied for EB (electron beam) exposure or EUV (extreme ultraviolet ray) exposure, and is preferably applied for EUV (extreme ultraviolet ray) exposure. In the development, an alkaline developer is used, a development temperature of 5 to 50° C. and a development time of 10 to 300 seconds are selected. Examples of the alkaline developer to be used include an aqueous solution of alkalies, such as: inorganic alkalies such as sodium hydroxide, potassium hydroxide, sodium carbonate, sodium silicate, sodium metasilicate, or ammonia water; first amines such as ethylamine or n-propylamine; second amines such as diethylamine or di-n-butylamine; third amines such as triethylamine or methyldiethylamine; alcoholamines such as dimethylethanolamine or triethanolamine; quaternary ammonium salts such as tetramethylammonium hydroxide, tetraethylammonium hydroxide, or choline; or cyclic amines such as pyrrole or piperidine. Furthermore, it is also possible to use the aqueous solution of alkalies with an appropriate amount of alcohols such as isopropyl alcohol or a nonionic surfactant added thereto. Among these, preferred developers are an aqueous solution of a quaternary ammonium salt, more preferably an aqueous solution of tetramethylammonium hydroxide and an aqueous solution of choline. Furthermore, a surfactant or the like can be added to these developers. In place of the alkaline developer, it is also possible to use a method of performing development with an organic solvent such as butyl acetate and developing the portion of the photoresist where the alkali dissolution rate has not been improved. Through the above steps, a semiconductor substrate having a patterned resist film can be produced.

Next, the resist underlayer film is dry-etched using the formed resist pattern as a mask. At that time, when the inorganic film is formed on the surface of the used semiconductor substrate, the surface of the inorganic film is exposed. When the inorganic film is not formed on the surface of the used semiconductor substrate, the surface of the semiconductor substrate is exposed. Thereafter, the semiconductor device can be produced through a step of processing the semiconductor substrate by a known method (dry etching method or the like).

### EXAMPLES

Hereinafter, the present invention will be described more specifically with reference to Examples, but the present invention is not limited thereto.

The weight average molecular weight of the polymers shown in the following Synthesis Examples and Comparative Synthesis Examples in the present specification is a measurement result by gel permeation chromatography (hereinafter, abbreviated as GPC). For the measurement, a GPC apparatus manufactured by Tosoh Corporation was used, and measurement conditions and the like are as follows.
GPC column: Shodex KF803L, Shodex KF802, Shodex KF801® (Showa Denko K.K.)
Column temperature: 40° C.
Solvent: dimethylformamide (DMF)
Flow rate: 1.0 ml/min
Standard sample: polystyrene (manufactured by Tosoh Corporation)

### Synthesis Example 1

Into 1.43 g of propylene glycol monomethyl ether acetate in a reaction vessel, 6.00 g of polyglycidyl methacrylate (manufactured by Tokyo Chemical Industry Co., Ltd.), 1.64 g of trifluoropropionic acid (manufactured by Tokyo Chemical Industry Co., Ltd.), and 0.14 g of tetrabutylphosphonium bromide (manufactured by ACROSS) were added and dissolved. The reaction vessel was purged with nitrogen, and then the mixture was reacted at 105° C. for 24 hours to obtain a polymer solution. The polymer solution does not cause cloudiness or the like even when cooled to room temperature, and has good solubility in propylene glycol monomethyl ether acetate. As a result of GPC analysis, the polymer in the obtained solution had a weight average molecular weight of 24000 in terms of standard polystyrene. The polymer obtained in the synthesis example has a structural unit represented by the following formula (1a).

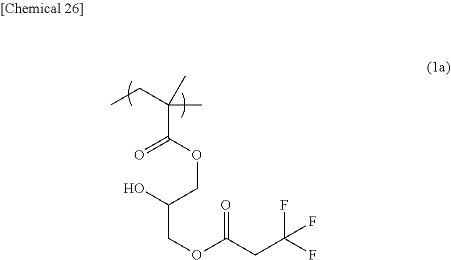

### Synthesis Example 2

Into 12.66 g of propylene glycol monomethyl ether acetate in a reaction vessel, 10.00 g of polyglycidyl methacrylate (manufactured by Maruzen Petrochemical Co., Ltd.), 5.31 g of 3-iodopropionic acid (manufactured by Tokyo Chemical Industry Co., Ltd.), and 0.14 g of tetrabutylphosphonium bromide (manufactured by ACROSS) were added and dissolved. The reaction vessel was purged with nitrogen, and then the mixture was reacted at 80° C. for 24 hours to obtain a polymer solution. The polymer solution does not cause cloudiness or the like even when cooled to room temperature, and has good solubility in propylene glycol monomethyl ether acetate. As a result of GPC analysis, the polymer in the obtained solution had a weight average molecular weight of 11000 in terms of standard polystyrene. The polymer obtained in the synthesis example has a structural unit represented by the following formula (1b).

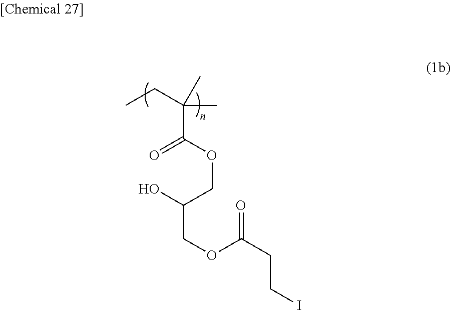

### Synthesis Example 3

In 50.00 g of propylene glycol monomethyl ether acetate, 9.86 g of glycidyl methacrylate (manufactured by Tokyo Chemical Industry Co., Ltd.), 10.00 g of 2-hydroxypropyl methacrylate (manufactured by Tokyo Chemical Industry Co., Ltd.), and 1.14 g of dimethyl 2,2-azobis(isobutyrate) were dissolved, and then the mixture was added to 35 g of propylene glycol monomethyl ether acetate kept at 90° C., and the mixture was reacted for 24 hours to obtain a polymer solution. The polymer solution does not cause cloudiness or the like even when cooled to room temperature, and has good solubility in propylene glycol monomethyl ether acetate. As a result of GPC analysis, the polymer in the obtained solution had a weight average molecular weight of 6000 in terms of standard polystyrene. The obtained solution was added dropwise to heptane (manufactured by KANTO CHEMICAL CO., INC.) for reprecipitation. The obtained precipitate was filtered and dried in a vacuum dryer at 40° C. for 24 hours to obtain a desired polymer. The polymer obtained in the synthesis example has a structural unit represented by the following formula (1c). In the following formula, n=50 mol % and m=50 mol %.

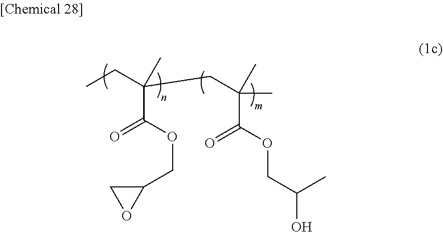

### Synthesis Example 4

Into 5.14 g of propylene glycol monomethyl ether in a reaction vessel, 8.00 g of the polymer obtained in Synthesis Example 3, 1.32 g of trifluoropropionic acid (manufactured by Tokyo Chemical Industry Co., Ltd.), and 0.067 g of tetrabutylphosphonium bromide (manufactured by ACROSS) were added and dissolved. The reaction vessel was purged with nitrogen, and then the mixture was reacted at 90° C. for 24 hours to obtain a polymer solution. The polymer solution does not cause cloudiness or the like even when cooled to room temperature, and has good solubility in propylene glycol monomethyl ether. As a result of GPC analysis, the polymer in the obtained solution had a weight average molecular weight of 14000 in terms of standard polystyrene. The polymer obtained in the synthesis example has a structural unit represented by the following formula (1d). In the following formula, n=50 mol % and m=50 mol %.

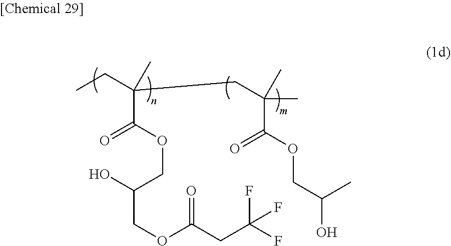

### Synthesis Example 5

Into 5.14 g of propylene glycol monomethyl ether in a reaction vessel, 8.00 g of the polymer obtained in Synthesis Example 3, 2.07 g of 3-iodopropionic acid (manufactured by Tokyo Chemical Industry Co., Ltd.), and 0.067 g of tetrabutylphosphonium bromide (manufactured by ACROSS) were added and dissolved. The reaction vessel was purged with nitrogen, and then the mixture was reacted at 90° C. for 24 hours to obtain a polymer solution. The polymer solution does not cause cloudiness or the like even when cooled to room temperature, and has good solubility in propylene glycol monomethyl ether. As a result of GPC analysis, the polymer in the obtained solution had a weight average molecular weight of 12000 in terms of standard polystyrene. The polymer obtained in the synthesis example has a structural unit represented by the following formula (1e). In the following formula, n=50 mol % and m=50 mol %.

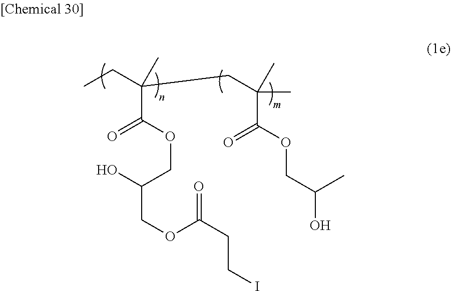

### Synthesis Example 6

Into 7.31 g of propylene glycol monomethyl ether acetate in a reaction vessel, 15.00 g of polyglycidyl methacrylate (manufactured by Maruzen Petrochemical Co., Ltd.), 2.95 g of propionic acid (manufactured by Tokyo Chemical Industry Co., Ltd.), and 0.21 g of tetrabutylphosphonium bromide (manufactured by ACROSS) were added and dissolved. The reaction vessel was purged with nitrogen, and then the mixture was reacted at 80° C. for 24 hours to obtain a polymer solution. The polymer solution does not cause cloudiness or the like even when cooled to room temperature, and has good solubility in propylene glycol monomethyl ether acetate. As a result of GPC analysis, the polymer in the obtained solution had a weight average molecular weight of 8300 in terms of standard polystyrene. The polymer obtained in the synthesis example has a structural unit represented by the following formula (1f).

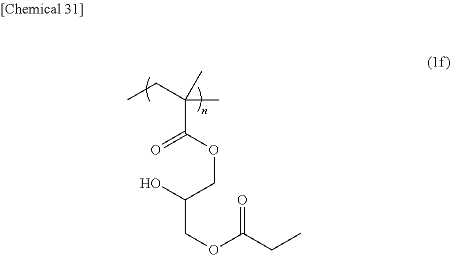

### Synthesis Example 7

In 37.00 g of propylene glycol monomethyl ether acetate, 15.00 g of 2-hydroxypropyl methacrylate (manufactured by Tokyo Chemical Industry Co., Ltd.) and 0.85 g of dimethyl 2,2-azobis (isobutyrate) were dissolved, and then the mixture was added to 26 g of propylene glycol monomethyl ether acetate kept at the boiling point, and the mixture was reacted for 24 hours to obtain a polymer solution. The polymer solution does not cause cloudiness or the like even when cooled to room temperature, and has good solubility in propylene glycol monomethyl ether acetate. As a result of GPC analysis, the polymer in the obtained solution had a weight average molecular weight of 6900 in terms of standard polystyrene. The obtained solution was added dropwise to heptane (manufactured by KANTO CHEMICAL CO., INC.) for reprecipitation. The obtained precipitate was filtered and dried in a vacuum dryer at 40° C. for 24 hours to obtain a desired polymer. The polymer obtained in the synthesis example has a structural unit represented by the following formula (1g).

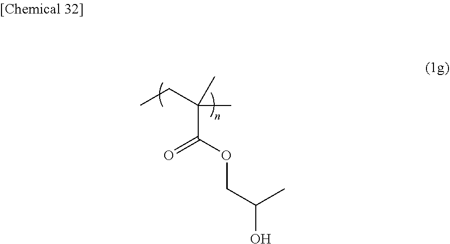

### Example 1

Into 0.76 g of the polymer solution obtained in Synthesis Example 1 (solid content: 15.1 wt %), 0.32 g of tetramethoxymethyl glycoluril (manufactured by Nihon Cytec Industries Inc.), 0.29 g of pyridinium phenol sulfonic acid, 44.3 g of propylene glycol monomethyl ether, and 4.34 g of propylene glycol monomethyl ether acetate were added and dissolved. Thereafter, filtration was performed using a polyethylene microfilter having a pore size of 0.05 μm to obtain a composition for forming a resist underlayer film for lithography.

### Example 2

Into 0.84 g of the polymer solution obtained in Synthesis Example 2 (solid content: 13.8 wt %), 0.32 g of tetramethoxymethyl glycoluril (manufactured by Nihon Cytec Industries Inc.), 0.29 g of pyridinium phenol sulfonic acid, 44.3 g of propylene glycol monomethyl ether, and 4.26 g of propylene glycol monomethyl ether acetate were added and dissolved. Thereafter, filtration was performed using a polyethylene microfilter having a pore size of 0.05 μm to obtain a composition for forming a resist underlayer film for lithography.

### Example 3

Into 0.70 g of the polymer solution obtained in Synthesis Example 4 (solid content: 16.6 wt %), 0.32 g of tetramethoxymethyl glycoluril (manufactured by Nihon Cytec Industries Inc.), 0.29 g of pyridinium phenol sulfonic acid, 44.3 g of propylene glycol monomethyl ether, and 4.40 g of propylene glycol monomethyl ether acetate were added and dissolved. Thereafter, filtration was performed using a polyethylene microfilter having a pore size of 0.05 μm to obtain a composition for forming a resist underlayer film for lithography.

### Example 4

Into 0.70 g of the polymer solution obtained in Synthesis Example 5 (solid content: 16.4 wt %), 0.32 g of tetramethoxymethyl glycoluril (manufactured by Nihon Cytec Industries Inc.), 0.29 g of pyridinium phenol sulfonic acid, 44.3 g of propylene glycol monomethyl ether, and 4.40 g of propylene glycol monomethyl ether acetate were added and dissolved. Thereafter, filtration was performed using a polyethylene microfilter having a pore size of 0.05 μm to obtain a composition for forming a resist underlayer film for lithography.

### Comparative Example 1

Into 0.86 g of the polymer solution obtained in Synthesis Example 6 (solid content: 13.3 wt %), 0.32 g of tetramethoxymethyl glycoluril (manufactured by Nihon Cytec Industries Inc.), 0.29 g of pyridinium phenol sulfonic acid, 44.3 g of propylene glycol monomethyl ether, and 4.30 g of propylene glycol monomethyl ether acetate were added and dissolved. Thereafter, filtration was performed using a polyethylene microfilter having a pore size of 0.05 μm to obtain a composition for forming a resist underlayer film for lithography.

### Comparative Example 2

The polymer obtained in Synthesis Example 7 was dissolved in propylene glycol monomethyl ether acetate to obtain a polymer solution. Into 0.79 g of the obtained polymer solution (solid content: 14.7 wt %), 0.32 g of tetramethoxymethyl glycoluril (manufactured by Nihon Cytec Industries Inc.), 0.29 g of pyridinium phenol sulfonic acid, 44.3 g of propylene glycol monomethyl ether, and 4.31 g of propylene glycol monomethyl ether acetate were added and dissolved. Thereafter, filtration was performed using a polyethylene microfilter having a pore size of 0.05 μm to obtain a composition for forming a resist underlayer film for lithography.

### [Elution Test in Photoresist Solvent]

Each of the compositions for forming a resist underlayer film of Example 1, Example 2, Example 3, Example 4, Comparative Example 1, and Comparative Example 2 was applied onto a silicon wafer as a semiconductor substrate with a spinner. The silicon wafer was placed on a hot plate and baked at 205° C. for 1 minute to form a resist underlayer film (film thickness: 5 nm). These resist underlayer films were immersed in a mixed solvent of propylene glycol monomethyl ether/propylene glycol monomethyl ether acetate=7/3 (mass ratio), which is a solvent used for a photoresist, and were confirmed to be insoluble in these solvents.

[Formation of Positive Resist Pattern with Electron Beam Drawing Apparatus]

Each of the compositions for forming a resist underlayer film of Example 1, Example 2, Example 3, Example 4, Comparative Example 1, and Comparative Example 2 was applied onto a silicon wafer with a spinner. The silicon wafer was baked at 205° C. for 60 seconds on a hot plate to form a resist underlayer film having a film thickness of 5 nm. An EUV positive resist solution (containing a methacrylic polymer) was spin-coated on the resist underlayer film, and heated at 110° C. for 60 seconds to form an EUV resist film. The resist film was exposed under a predetermined condition using an electron beam drawing apparatus (ELS-G130). After the exposure, the film was baked (PEB) at 90° C. for 60 seconds, cooled on a cooling plate to room temperature, and developed with an alkaline developer (2.38% TMAH) to form a line-and-space pattern with a CD size of 22 nm and a pitch of 44 nm. A scanning electron microscope (CG4100; manufactured by Hitachi High-Technologies Corporation) was used for measuring the length of the resist pattern. In the formation of the resist pattern, a case where a line pattern having a CD size of 22 nm was formed was indicated as “good”, and a case where the line pattern was collapsed or peeled was indicated as “poor”. In addition, the exposure amount required for forming a line pattern having a CD size of 22 nm was compared, and a normalized exposure amount value was calculated. The normalized exposure amount value is a relative value when the required exposure amount of Comparative Example 1 is 1.0.

TABLE 1

| | CD size of 22 nm | Normalized exposure |
|---|---|---|
| | Line pattern | amount value |
| Example 1 | good | 0.96 |
| Example 2 | good | 0.88 |
| Example 3 | good | 0.95 |
| Example 4 | good | 0.90 |
| Comparative Example 1 | poor | 1.0 |
| Comparative Example 2 | poor | No pattern |

In all of Example 1, Example 2, Example 3, and Example 4, as compared with Comparative Example 1 and Comparative Example 2, it was possible to suppress the collapse and peeling of the line pattern, and it was suggested that the line pattern had a good pattern forming ability. In addition, as for the required exposure amount, it was shown that, each of Example 1, Example 2, Example 3, and Example 4 can form a pattern with a smaller exposure amount as compared with Comparative Example 1 and Comparative Example 2.

### INDUSTRIAL APPLICABILITY

The present invention is suitably employed for a composition for forming a resist underlayer film to form a resist underlayer film capable of forming a desired resist pattern, and a method for producing a semiconductor substrate having a resist pattern and a method for producing a semiconductor device using the composition for forming a resist underlayer film.

1. A composition for forming a resist underlayer film, the composition comprising: a polymer containing a unit structure (A) represented by the following formula (1); and a solvent: 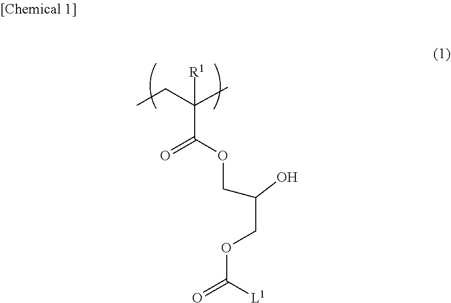
wherein, in the formula (1), R¹ represents a hydrogen atom or an alkyl group having 1 to 10 carbon atoms; and L¹ represents a monovalent organic group selected from an alkyl group having 1 to 10 carbon atoms, an aryl group having 6 to 40 carbon atoms, and a monovalent heterocyclic group, where at least one hydrogen atom which the alkyl group, the aryl group, and the monovalent heterocyclic group have is substituted with a halogen atom, and where at least one hydrogen atom which the alkyl group, the aryl group, and the monovalent heterocyclic group have may be substituted with a hydroxy group.

2. The composition for forming a resist underlayer film according to claim 1, wherein the halogen atom is a fluorine atom or an iodine atom.

3. The composition for forming a resist underlayer film according to claim 1, wherein the polymer further contains a unit structure (B) that has a side chain having a monovalent organic group selected from an alkyl group having 1 to 10 carbon atoms, an aliphatic ring having 3 to 10 carbon atoms, and an aryl group having 6 to 40 carbon atoms.

4. The composition for forming a resist underlayer film according to claim 3, wherein the unit structure (B) is represented by the following formula (2): 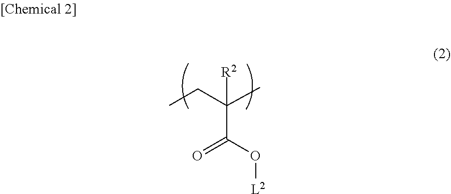
wherein, in the formula (2), R² represents a hydrogen atom or an alkyl group having 1 to 10 carbon atoms; and L² represents a monovalent organic group selected from an alkyl group having 1 to 10 carbon atoms and an aryl group having 6 to 40 carbon atoms, where at least one hydrogen atom which the alkyl group and the aryl group have may be substituted with a hydroxy group.

5. The composition for forming a resist underlayer film according to claim 1, the composition further comprising an acid generator.

6. The composition for forming a resist underlayer film according to claim 1, the composition further comprising a crosslinking agent.

7. A resist underlayer film, being a baked product of a coating film formed from the composition for forming a resist underlayer film according to any one of claims 1 to 6.

8. A method for producing a semiconductor substrate having a patterned resist film, the method comprising:
a step of applying the composition for forming a resist underlayer film according to any one of claims 1 to 6 on a semiconductor substrate, followed by baking, to form a resist underlayer film;
a step of applying a resist on the resist underlayer film, followed by baking, to form a resist film;
a step of exposing the semiconductor substrate coated with the resist underlayer film and the resist film; and
a step of developing the exposed resist film to subject the resist film to patterning.

9. A method for producing a semiconductor device, the method comprising:
a step of forming a resist underlayer film formed from the composition for forming a resist underlayer film according to any one of claims 1 to 6 on a semiconductor substrate;
a step of forming a resist film on the resist underlayer film;
a step of irradiating the resist film with light or an electron beam, followed by development, to form a resist pattern;
a step of etching the resist underlayer film through the formed resist pattern to form a patterned resist underlayer film; and
a step of processing the semiconductor substrate through the patterned resist underlayer film.
